(19) United States
(12) Patent Application Publication
(10) Pub. No.: US 2023/0301216 A1
(43) Pub. Date: Sep. 21, 2023

(54) RESISTIVE MEMORY DEVICE AND METHOD OF MANUFACTURING THE SAME

(71) Applicant: DB HITEK CO., LTD., Seoul (KR)

(72) Inventor: Tae Woo KIM, Icheon-si (KR)

(21) Appl. No.: 18/122,118

(22) Filed: Mar. 15, 2023

(30) Foreign Application Priority Data
Mar. 16, 2022 (KR) 10-2022-0032769

(51) Int. Cl. H10N 70/00; H10B 63/00; H10N 70/20

(52) U.S. Cl. CPC H10N 70/841; H10B 63/30; H10N 70/24; H10N 70/063

(57) ABSTRACT

A resistive memory device includes a lower electrode having a flat upper surface, a resistance change layer formed on the lower electrode, and an upper electrode formed on the resistance change layer. The upper surface of the lower electrode is wider than a lower surface of the lower electrode.

### CROSS-REFERENCE TO RELATED APPLICATION

This application claims the priority benefit of Korean Patent Application No. 10-2022-0032769, filed on Mar. 16, 2022, and all the benefits accruing therefrom under 35 U.S.C. § 119, the contents of which are incorporated by reference in their entirety.

### TECHNICAL FIELD

The present disclosure relates to a resistive memory device and a method of manufacturing the same. More specifically, the present disclosure relates to a resistive memory device that can be used as a Resistive Random Access Memory (ReRAM) device and stores data using a difference in resistance state of a resistance change layer, and a method of manufacturing the resistive memory device.

### BACKGROUND

The resistive memory device may have advantages of having simple structure, high operating speed, and low power consumption. Unlike a flash memory device that stores charge, the resistive memory device may store data through the difference in resistance state of the resistance change layer. For example, the resistive memory device may have a high resistance state (HRS) and a low resistance state (LRS), and in addition, it may have resistance states of various stages depending on the material and structure constituting the device.

The switching operation of the resistive memory device includes a forming step in which a conductive filament is formed in an initial state to be in a low resistance state, a RESET operation step in which the conductive filament is cut and the resistance increases, and a SET operation step in which a conductive filament is generated again to lower the resistance.

The resistive memory device may include a lower electrode, a resistance change layer formed on the lower electrode, and an upper electrode formed on the resistance change layer. On the other hand, when a divot-shaped defect occurs on an upper surface of the lower electrode while forming the lower electrode, thickness uniformity of the resistance change layer formed on the lower electrode may deteriorate, and thus operation performance of the resistive memory device may deteriorate.

### SUMMARY

The present disclosure provides a resistive memory device capable of improving thickness uniformity of a resistance change layer and a method of manufacturing the same.

In accordance with an aspect of the present disclosure, a resistive memory device may include a lower electrode having a flat upper surface, a resistance change layer formed on the lower electrode, and an upper electrode formed on the resistance change layer. Particularly, the upper surface of the lower electrode may be wider than a lower surface of the lower electrode.

In accordance with some embodiments of the present disclosure, the lower electrode may have an inclined side surface so that a width of the lower electrode is increased upwardly.

In accordance with some embodiments of the present disclosure, the resistive memory device may further include a conductive layer formed on the resistance change layer. In such case, the upper electrode may be formed on the conductive layer.

In accordance with some embodiments of the present disclosure, the resistive memory device may further include a transistor formed on the substrate, a first insulating layer formed on the substrate and the transistor, a first contact plug electrically connected to the transistor through the first insulating layer, and a second insulating layer formed on the first insulating layer and the first contact plug and having an opening exposing a portion of an upper surface of the first contact plug. In such case, the lower electrode may be formed in the opening.

In accordance with some embodiments of the present disclosure, the opening may have an inclined inner side surface so that a width of the opening is increased upwardly.

In accordance with some embodiments of the present disclosure, the first insulating layer may have a first contact hole, a first adhesive layer and a first diffusion barrier layer may be formed on a bottom surface and an inner side surface of the first contact hole, and the first contact plug may be formed on the first diffusion barrier layer to fill the first contact hole.

In accordance with some embodiments of the present disclosure, the resistance change layer may be electrically insulated from the first adhesive layer by the second insulating layer.

In accordance with some embodiments of the present disclosure, the resistive memory device may further include a third insulating layer formed on the upper electrode, a second contact plug electrically connected to the upper electrode through the third insulating layer, and a metal wiring pattern formed on the third insulating layer and the second contact plug.

In accordance with some embodiments of the present disclosure, the third insulating layer may have a second contact hole, a second adhesive layer and a second diffusion barrier layer may be formed on a bottom surface and an inner side surface of the second contact hole, and the second contact plug may be formed on the second diffusion barrier layer to fill the second contact hole.

In accordance with another aspect of the present disclosure, a method of manufacturing a resistive memory device may include forming a lower electrode having a flat upper surface, forming a resistance change layer on the lower electrode, and forming an upper electrode on the resistance change layer. Particularly, the upper surface of the lower electrode may be wider than a lower surface of the lower electrode.

In accordance with some embodiments of the present disclosure, the lower electrode may have an inclined side surface so that a width of the lower electrode is increased upwardly.

In accordance with some embodiments of the present disclosure, the method may further include forming a transistor on a substrate, forming a first insulating layer on the substrate and the transistor, forming a first contact plug electrically connected to the transistor through the first insulating layer, forming a second insulating layer on the first insulating layer and the first contact plug, and forming an opening exposing a portion of an upper surface of the first contact plug by partially removing the second insulating layer. In such case, the lower electrode may be formed in the opening.

In accordance with some embodiments of the present disclosure, the opening may have an inclined inner side surface so that a width of the opening is increased upwardly.

In accordance with some embodiments of the present disclosure, forming the opening may include forming a photoresist pattern on the second insulating layer exposing a portion of the second insulating layer corresponding to the opening, forming a recess in the second insulating layer by performing a first etching process using the photoresist pattern as an etching mask, removing the photoresist pattern, and forming the opening by performing a second etching process.

In accordance with some embodiments of the present disclosure, forming the opening may include forming a photoresist pattern having a first opening exposing a portion of the second insulating layer on the second insulating layer, forming a second opening by performing a photoresist reflow process, the second opening having an inclined inner side surface so that a width of the second opening is increased upwardly, and forming the opening by performing an etching process using the photoresist pattern as an etching mask.

In accordance with some embodiments of the present disclosure, forming the lower electrode may include forming a conductive layer on the second insulating layer and inner surfaces of the opening, and removing a portion of the conductive layer to expose an upper surface of the second insulating layer to form the lower electrode in the opening.

In accordance with some embodiments of the present disclosure, the method may further include forming a first contact hole exposing a portion of the transistor through the first insulating layer, forming a first adhesive layer on a bottom surface and an inner side surface of the first contact hole, and forming a first diffusion barrier layer on the first adhesive layer. In such case, the first contact plug may be formed on the first diffusion barrier layer to fill the first contact hole.

In accordance with some embodiments of the present disclosure, the resistance change layer may be formed on the lower electrode and the second insulating layer and may be electrically insulated from the first adhesive layer by the second insulating layer.

In accordance with some embodiments of the present disclosure, the method may further include forming a conductive layer on the resistance change layer. In such case, the upper electrode may be formed on the conductive layer.

In accordance with some embodiments of the present disclosure, the method may further include forming a third insulating layer on the upper electrode, forming a second contact plug electrically connected to the upper electrode through the third insulating layer, and forming a metal wiring pattern on the third insulating layer and the second contact plug.

In accordance with the embodiments of the present disclosure as described above, the opening exposing the portion of the upper surface of the first contact plug through the second insulating layer may have the inclined inner surface so as to increase in width upward, and the lower electrode formed in the opening may have the flat upper surface. Thus, the problem of divot-shaped defects occurring on the upper surface of the lower electrode may be solved. In particular, the thickness uniformity of the resistance change layer formed on the lower electrode may be significantly improved, and the operating performance of the resistive memory device may thus be significantly improved.

The above summary of the present disclosure is not intended to describe each illustrated embodiment or every implementation of the present disclosure. The detailed description and claims that follow more particularly exemplify these embodiments.

### BRIEF DESCRIPTION OF THE DRAWINGS

Embodiments can be understood in more detail from the following description taken in conjunction with the accompanying drawings, in which:

FIG. 1 is a schematic cross-sectional view illustrating a resistive memory device in accordance with an embodiment of the present disclosure;

FIGS. 2 to 15 are schematic cross-sectional views illustrating a method of manufacturing the resistive memory device as shown in FIG. 1; and

FIGS. 16 to 18 are schematic cross-sectional views illustrating a method of manufacturing the resistive memory device as shown in FIG. 1 in accordance with another embodiment of the present disclosure.

While various embodiments are amenable to various modifications and alternative forms, specifics thereof have been shown by way of example in the drawings and will be described in detail. It should be understood, however, that the intention is not to limit the claimed inventions to the particular embodiments described. On the contrary, the intention is to cover all modifications, equivalents, and alternatives falling within the spirit and scope of the subject matter as defined by the claims.

### DETAILED DESCRIPTION

Hereinafter, embodiments of the present disclosure are described in more detail with reference to the accompanying drawings. However, the present disclosure is not limited to the embodiments described below and is implemented in various other forms. Embodiments below are not provided to fully complete the present disclosure but rather are provided to fully convey the range of the present disclosure to those skilled in the art.

In the specification, when one component is referred to as being on or connected to another component or layer, it can be directly on or connected to the other component or layer, or an intervening component or layer may also be present. Unlike this, it will be understood that when one component is referred to as directly being on or directly connected to another component or layer, it means that no intervening component is present. Also, though terms like a first, a second, and a third are used to describe various regions and layers in various embodiments of the present disclosure, the regions and the layers are not limited to these terms.

Terminologies used below are used to merely describe specific embodiments, but do not limit the present disclosure. Additionally, unless otherwise defined here, all the terms including technical or scientific terms, may have the same meaning that is generally understood by those skilled in the art.

Embodiments of the present disclosure are described with reference to schematic drawings of ideal embodiments. Accordingly, changes in manufacturing methods and/or allowable errors may be expected from the forms of the drawings. Accordingly, embodiments of the present disclosure are not described being limited to the specific forms or areas in the drawings, and include the deviations of the forms. The areas may be entirely schematic, and their forms may not describe or depict accurate forms or structures in any given area, and are not intended to limit the scope of the present disclosure.

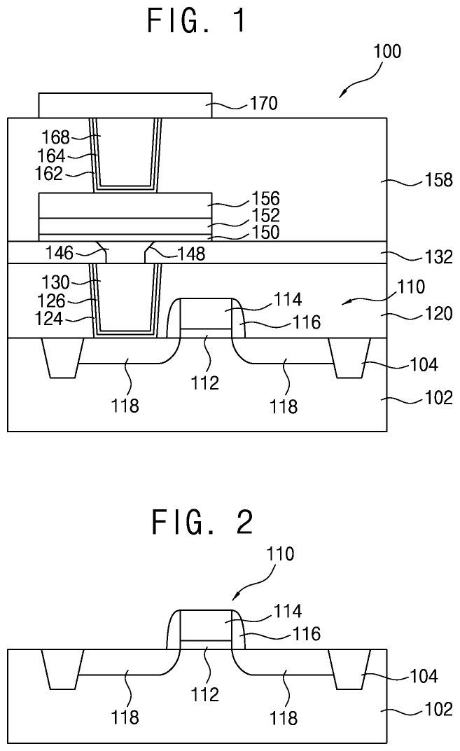

FIG. 1 is a schematic cross-sectional view illustrating a resistive memory device in accordance with an embodiment of the present disclosure.

Referring to FIG. 1, a resistive memory device 100, in accordance with an embodiment of the present disclosure, may include a lower electrode 146 formed on a substrate 102, a resistance change layer 150 formed on the lower electrode 146, and an upper electrode 156 formed on the resistance change layer 150. Further, the resistive memory device 100 may include a transistor 110 formed on the substrate 102, a first insulating layer 120 formed on the substrate 102 and the transistor 110, and a first contact plug 130 electrically connected to the transistor 110 through the first insulating layer 120.

The transistor 110 may include a gate insulating layer 112 formed on the substrate 102, a gate electrode 114 formed on the gate insulating layer 112, gate spacers 116 formed on side surfaces of the gate electrode 114, and impurity diffusion regions 118 formed on surface portions of the substrate 102 and functioning as source/drain regions. In such case, the first contact plug 130 may be formed on one of the impurity diffusion regions 118.

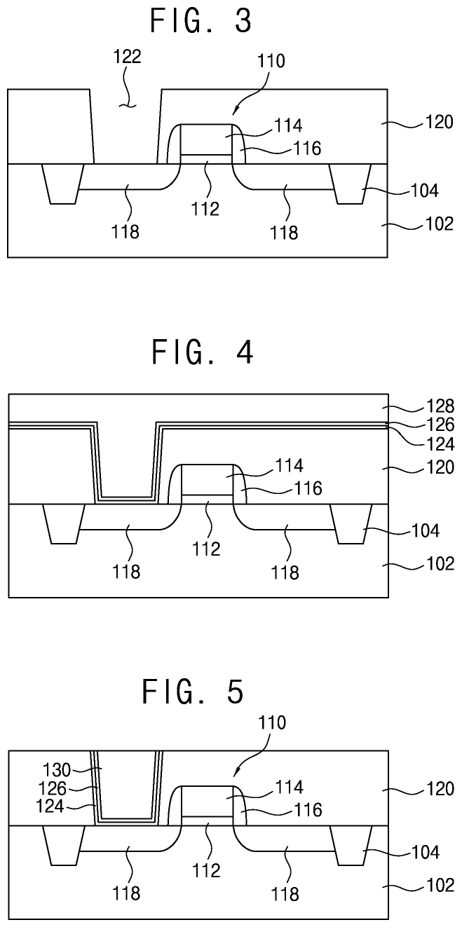

The first insulating layer 120 may have a first contact hole 122 (refer to FIG. 3) exposing a portion of an upper surface of one of the impurity diffusion regions 118, and the first contact plug 130 may be formed in the first contact hole 122. In particular, a first adhesive layer 124 and a first diffusion barrier layer 126 may be formed on a bottom surface and an inner side surface of the first contact hole 122, and the first contact plug 130 may be formed on the first diffusion barrier layer 126 to fill the first contact hole 122. For example, the first adhesive layer 124 may include titanium, and the first diffusion barrier layer 126 may include titanium nitride. The first contact plug 130 may include tungsten, and the first diffusion barrier layer 126 may be used to prevent metal diffusion, that is, tungsten diffusion, from the first contact plug 130.

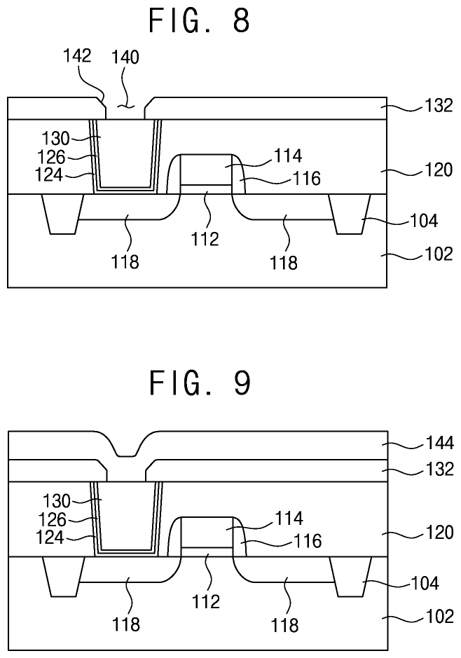

The lower electrode 146 may be formed on the first contact plug 130. For example, a second insulating layer 132 having an opening 140 (refer to FIG. 8) exposing a portion of an upper surface of the first contact plug 130 may be formed on the first insulating layer 120 and the first contact plug 130, and the lower electrode 146 may be formed in the opening 140. In particular, the opening 140 may have an inclined inner side surface 142 (refer to FIG. 8) so that a width of the opening 140 is increased upwardly, and accordingly, the lower electrode 146 may have an inclined side surface 148 so that a width of the lower electrode 146 is increased upwardly. Further, an upper surface of the lower electrode 146 may be formed wider than a lower surface of the lower electrode 146. As a result, the upper surface of the lower electrode 146 may be formed flat, and thickness uniformity of the resistance change layer 150 formed on the upper surface of the lower electrode 146 may be improved.

In accordance with an embodiment of the present disclosure, the lower electrode 146 may include titanium nitride, thereby preventing metal diffusion, that is, tungsten diffusion, from the first contact plug 130 to the resistance change layer 150. The resistance change layer 150 may include silicon oxide and may be formed on the second insulating layer 132 and the lower electrode 146. For example, although not shown, the resistance change layer 150 may include a first silicon oxide layer formed on the second insulating layer 132 and the lower electrode 146, and a second silicon oxide layer formed on the first silicon oxide layer. In particular, the oxygen content of the first silicon oxide layer may be greater than that of the second silicon oxide layer, and further, the number of oxygen vacancies in the first silicon oxide layer may be smaller than the number of oxygen vacancies in the second silicon oxide layer. In such case, although the titanium nitride has a relatively high oxygen affinity, the RESET operation of the resistive memory device 100 may be stably performed because the number of oxygen vacancies in the first silicon oxide layer is relatively small.

The resistance change layer 150 may be electrically insulated from the first adhesive layer 124 by the second insulating layer 132. For example, the second insulating layer 132 may include silicon nitride, and thus metal diffusion, that is, titanium diffusion, from the first adhesive layer 124 to the resistance change layer 150 may be prevented.

In accordance with an embodiment of the present disclosure, the resistive memory device 100 may include a conductive layer 152 formed on the resistance change layer 150. In such case, the upper electrode 156 may be formed on the conductive layer 152. For example, the conductive layer 152 may include tantalum nitride, and the upper electrode 156 may include aluminum. Accordingly, metal diffusion, that is, aluminum diffusion, from the upper electrode 156 to the resistance change layer 150 may be prevented by the conductive layer 152.

In addition, the resistive memory device 100 may include a third insulating layer 158 formed on the second insulating layer 132 and the upper electrode 156, a second contact plug 168 electrically connected to the upper electrode 156 through the third insulating layer 158, and a metal wiring pattern 170 formed on the third insulating layer 158 and the second contact plug 168. For example, the third insulating layer 158 may include silicon oxide, the second contact plug 168 may include tungsten, and the metal wiring pattern 170 may include aluminum.

The third insulating layer 158 may have a second contact hole 160 (refer to FIG. 13) partially exposing the upper electrode 156, and a second adhesive layer 162 and a second diffusion barrier layer 164 may be formed on a bottom surface and an inner side surface of the second contact hole 160. In such case, the second contact plug 168 may be formed on the second diffusion barrier layer 164 to fill the second contact hole 160. For example, the second adhesive layer 162 may include titanium, and the second diffusion barrier layer 164 may include titanium nitride.

FIGS. 2 to 15 are schematic cross-sectional views illustrating a method of manufacturing the resistive memory device as shown in FIG. 1.

Referring to FIG. 2, device isolation regions 104 may be formed in surface portions of a substrate 102 such as a silicon wafer to define an active region. For example, the device isolation regions 104 may be formed through a shallow trench isolation (STI) process and may be made of silicon oxide and/or silicon nitride.

A transistor 110 may be formed on the active region of the substrate 102. For example, a gate insulating layer 112 may be formed on the substrate 102, and a gate electrode 114 may be formed on the gate insulating layer 112. The gate insulating layer 112 may be a silicon oxide layer formed through a thermal oxidation process, and the gate electrode 114 may be made of impurity-doped polysilicon. In addition, gate spacers 116 may be formed on side surfaces of the gate electrode 114.

Impurity diffusion regions 118 serving as source/drain regions may be formed in surface portions of the substrate 102 adjacent to the gate electrode 114. For example, the impurity diffusion regions 118 may be formed by an ion implantation process and a heat treatment process. In addition, although not shown, ohmic contact layers (not shown) may be formed on surface portions of the impurity diffusion regions 118, respectively. For example, cobalt silicide layers may be formed on surface portions of the impurity diffusion regions 118, respectively.

Referring to FIG. 3, a first insulating layer 120 such as a silicon oxide layer may be formed on the substrate 102, and a first contact hole 122 may then be formed to partially expose a surface portion of the substrate 102, for example, one of the impurity diffusion regions 118. For example, a photoresist pattern (not shown) exposing a portion of the first insulating layer 120 may be formed on the first insulating layer 120, and the first contact hole 122 may be formed through an anisotropic etching process using the photoresist pattern as an etching mask.

Referring to FIG. 4, a first adhesive layer 124, for example, a titanium layer may be formed on the first insulating layer 120, an inner side surface of the first contact hole 122, and the surface portion of the substrate 102 exposed by the first contact hole 122, and a first diffusion barrier layer 126, for example, a titanium nitride layer, may be formed on the first adhesive layer 124. Further, a first conductive layer 128, for example, a tungsten layer, may be formed on the first diffusion barrier layer 126 so as to fill the first contact hole 122.

Referring to FIG. 5, the first conductive layer 128, the first diffusion barrier layer 126, and the first adhesive layer 124 may be partially removed to expose the first insulating layer 120, and a first contact plug 130 may thus be formed in the first contact hole 122. For example, the first conductive layer 128, the first diffusion barrier layer 126, and the first adhesive layer 124 may be partially removed by a chemical mechanical polishing (CMP) process. In particular, as shown in FIG. 5, the first adhesive layer 124 and the first diffusion barrier layer 126 may be upwardly exposed by the chemical mechanical polishing process.

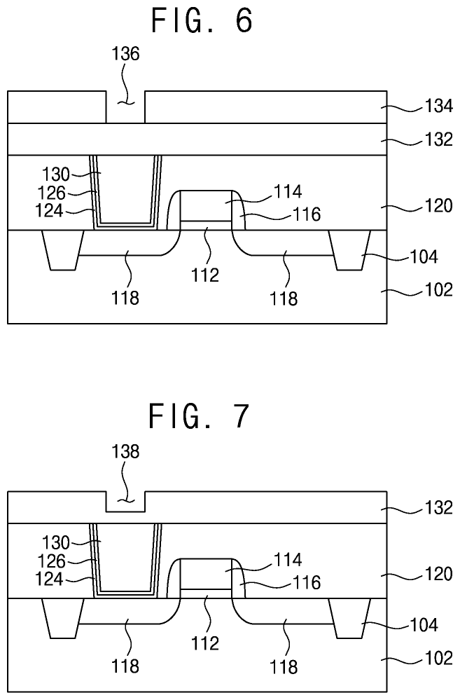

Referring to FIG. 6, a second insulating layer 132 may be formed on the first insulating layer 120 and the first contact plug 130, and a photoresist pattern 134 having an opening 136 corresponding to a portion of an upper surface of the first contact plug 130 may be formed on the second insulating layer 132.

Referring to FIG. 7, a first etching process using the photoresist pattern 134 as an etching mask, for example, a first anisotropic etching process may be performed, and thus a recess 138 corresponding to the portion of the upper surface of the first contact plug 130 may be formed in the second insulating layer 132. For example, the first etching process may be performed for a predetermined time, thereby partially removing the second insulating layer 132 and forming the recess 138. After forming the recess 138, the photoresist pattern 134 may be removed through a strip process and/or an ashing process.

Referring to FIG. 8, after removing the photoresist pattern 134, a second etching process may be performed to form an opening 140 exposing the portion of the upper surface of the first contact plug 130. For example, the second etching process may be an anisotropic etching process without using an etching mask, and the second insulating layer 132 may be partially removed by the second etching process to expose the portion of the upper surface of the first contact plug 130. In particular, during the second etching process, an upper edge portion of the opening 140 may be removed by ion bombardment, and thus the opening 140 may have an inclined inner surface 142 so that a width of the opening 140 is increased upwardly.

Referring to FIG. 9, a second conductive layer 144 may be formed on the second insulating layer 132 and inner surfaces of the opening 140. For example, a titanium nitride layer may be formed to a predetermined thickness on the second insulating layer 132 and the inner surfaces of the opening 140 through a sputtering process or a chemical vapor deposition process so that the opening 140 is sufficiently filled with titanium nitride.

Referring to FIG. 10, the second conductive layer 144 may be partially removed to expose an upper surface of the second insulating layer 132, and thus a lower electrode 146 may be formed in the opening 140. For example, a planarization process such as a chemical mechanical polishing process may be performed until the upper surface of the second insulating layer 132 is exposed. In particular, because the width of the opening 140 increases upward, the problem of divot-shaped defects occurring on an upper surface of the lower electrode 146 may be solved, and as a result, the upper surface of the lower electrode 146 may be formed flat. In addition, the upper surface of the lower electrode 146 may be formed wider than a lower surface of the lower electrode 146, and a side surface of the lower electrode 146 may be inclined so that a width of the lower electrode 146 increases upward.

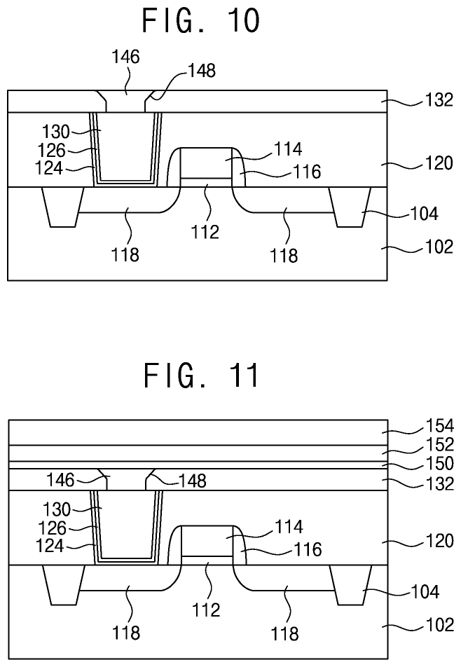

Referring to FIG. 11, a resistance change layer 150 may be formed on the second insulating layer 132 and the lower electrode 146. The resistance change layer 150 may be made of silicon oxide. For example, although not shown, the resistance change layer 150 may include a first silicon oxide layer formed on the second insulating layer 132 and the lower electrode 146, and a second silicon oxide layer formed on the first silicon oxide layer. In particular, the oxygen content of the first silicon oxide layer may be greater than that of the second silicon oxide layer, and further, the number of oxygen vacancies in the first silicon oxide layer may be smaller than the number of oxygen vacancies in the second silicon oxide layer. For example, the first silicon oxide layer and the second silicon oxide layer may be formed through chemical vapor deposition or physical vapor deposition.

Then, a third conductive layer 152 may be formed on the resistance change layer 150, and a fourth conductive layer 154 may be formed on the third conductive layer 152. For example, a tantalum nitride layer may be formed on the resistance change layer 150 as the third conductive layer 152, and an aluminum layer may be formed on the third conductive layer 152 as the fourth conductive layer 154.

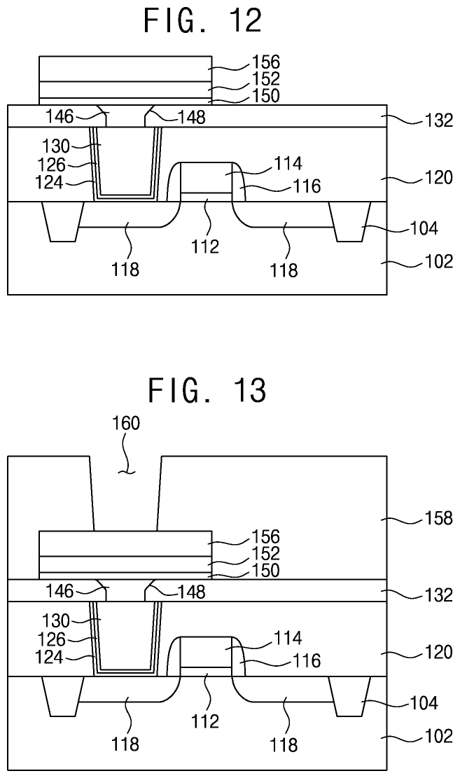

Referring to FIG. 12, the resistance change layer 150, the third conductive layer 152, and the fourth conductive layer 154 may be patterned. For example, a photoresist pattern (not shown) may be formed on the fourth conductive layer 154, and an upper electrode 156 may be formed from the fourth conductive layer 154 by performing an anisotropic etching process using the photoresist pattern as an etching mask. Then, the third conductive layer 152 and the resistance change layer 150 may be sequentially patterned using the photoresist pattern. In such case, the third conductive layer 152 may function as a diffusion barrier layer for preventing metal diffusion, that is, aluminum diffusion from the upper electrode 156 to the resistance change layer 150.

In particular, the resistance change layer 150 may be formed on the second insulating layer 132 and the lower electrode 146. In such case, the resistance change layer 150 may be electrically insulated from the first adhesive layer 124 by the second insulating layer 132. For example, the second insulating layer 132 may be made of silicon nitride and may function as a diffusion barrier layer for preventing metal diffusion, that is, titanium diffusion from the first adhesive layer 124 to the resistance change layer 150.

Referring to FIG. 13, a third insulating layer 158 such as a silicon oxide layer may be formed on the second insulating layer 132 and the upper electrode 156, and a second contact hole 160 may be formed through the third insulating layer 158 to expose a portion of an upper surface of the upper electrode 156. For example, after forming a photoresist pattern (not shown) having an opening exposing the portion of the upper surface of the upper electrode 156 on the third insulating layer 158, the second contact hole 160 may be formed by performing an anisotropic etching process using the photoresist pattern as an etching mask.

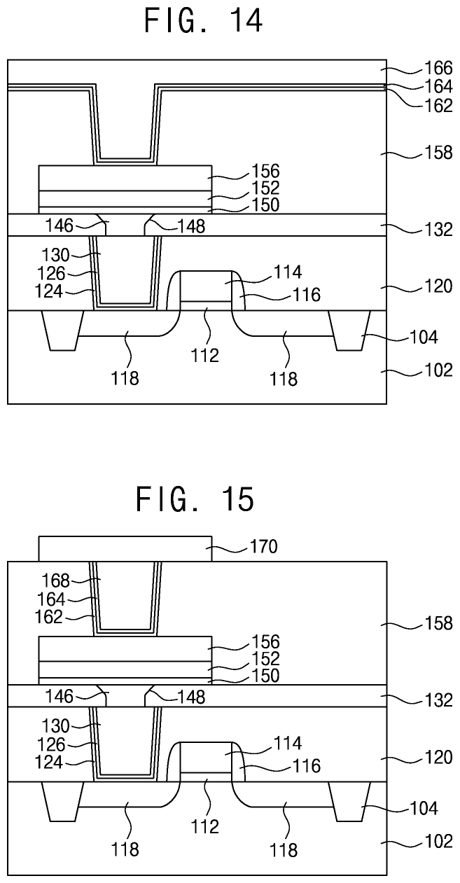

Referring to FIG. 14, a second adhesive layer 162 and a second diffusion barrier layer 164 may be formed on the third insulating layer 158, an inner side surface of the second contact hole 160, and the upper surface portion of the upper electrode 156 exposed by the second contact hole 160. Further, a fifth conductive layer 166 may be formed on the second diffusion barrier layer 164 to fill the second contact hole 160. For example, a titanium layer and a titanium nitride layer may be formed as the second adhesive layer 162 and the second diffusion barrier layer 164, respectively, and a tungsten layer may be formed as the fifth conductive layer 166.

Referring to FIG. 15, the fifth conductive layer 166, the second diffusion barrier layer 164, and the second adhesive layer 162 may be partially removed to expose the third insulating layer 158, and thus a second contact plug 168 may be formed in the second contact hole 160. For example, the fifth conductive layer 166, the second diffusion barrier layer 164, and the second adhesive layer 162 may be partially removed through a chemical mechanical polishing process.

Then, a metal wiring pattern 170 may be formed on the second contact plug 168. For example, a sixth conductive layer (not shown) such as an aluminum layer may be formed on the third insulating layer 158 and the second contact plug 168, and the metal wiring pattern 170 may be formed by patterning the sixth conductive layer.

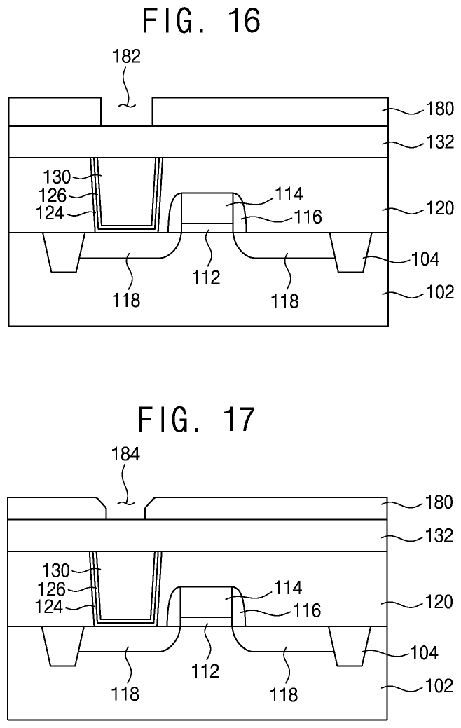

FIGS. 16 to 18 are schematic cross-sectional views illustrating a method of manufacturing the resistive memory device as shown in FIG. 1 in accordance with another embodiment of the present disclosure.

Referring to FIG. 16, a photoresist pattern 180 having a first opening 182 exposing a portion of the second insulating layer 132 may be formed on the second insulating layer 132. In such case, the first opening 182 may be formed to correspond to a portion of an upper surface of the first contact plug 130.

Referring to FIG. 17, a photoresist reflow process may be performed to form a second opening 184 having an inclined inner surface so that a width of the second opening 184 is increased upwardly. For example, the photoresist reflow process may be performed at a temperature of about 150° C. to about 200° C.

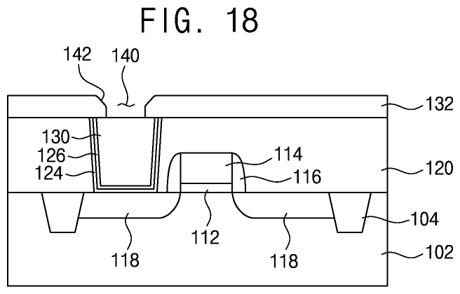

Referring to FIG. 18, an anisotropic etching process using the photoresist pattern 180 as an etching mask may be performed, and thus an opening 140 exposing the portion of the upper surface of the first contact plug 130 may be formed through the second insulating layer 132. In such case, the photoresist pattern 180 may be removed by the anisotropic etching process, and thus the opening 140 may have an inclined inner surface 142 so that a width of the opening 140 is increased upwardly. Then, the lower electrode 146 may be formed in the opening 140.

In accordance with the embodiments of the present disclosure as described above, the opening 140 exposing the portion of the upper surface of the first contact plug 130 through the second insulating layer 132 may have the inclined inner surface 142 so as to increase in width upward, and the lower electrode 146 formed in the opening 140 may have a flat upper surface. Thus, the problem of divot-shaped defects occurring on the upper surface of the lower electrode 146 may be solved. In particular, the thickness uniformity of the resistance change layer 150 formed on the lower electrode 146 may be significantly improved, and the operating performance of the resistive memory device 100 may thus be significantly improved.

Although the example embodiments of the present disclosure have been described with reference to the specific embodiments, they are not limited thereto. Therefore, it will be readily understood by those skilled in the art that various modifications and changes can be made thereto without departing from the spirit and scope of the present disclosure defined by the appended claims.

1. A resistive memory device comprising:
a lower electrode having a flat upper surface;
a resistance change layer formed on the lower electrode; and
an upper electrode formed on the resistance change layer,
wherein the upper surface of the lower electrode is wider than a lower surface of the lower electrode.

2. The resistive memory device of claim 1, wherein the lower electrode has an inclined side surface so that a width of the lower electrode is increased upwardly.

3. The resistive memory device of claim 1, further comprising a conductive layer formed on the resistance change layer,
wherein the upper electrode is formed on the conductive layer.

4. The resistive memory device of claim 1, further comprising:
a transistor formed on the substrate;
a first insulating layer formed on the substrate and the transistor;
a first contact plug electrically connected to the transistor through the first insulating layer; and
a second insulating layer formed on the first insulating layer and the first contact plug and having an opening exposing a portion of an upper surface of the first contact plug,
wherein the lower electrode is formed in the opening.

5. The resistive memory device of claim 4, wherein the opening has an inclined inner side surface so that a width of the opening is increased upwardly.

6. The resistive memory device of claim 4, wherein the first insulating layer has a first contact hole,
a first adhesive layer and a first diffusion barrier layer are formed on a bottom surface and an inner side surface of the first contact hole, and
the first contact plug is formed on the first diffusion barrier layer to fill the first contact hole.

7. The resistive memory device of claim 6, wherein the resistance change layer is electrically insulated from the first adhesive layer by the second insulating layer.

8. The resistive memory device of claim 1, further comprising:
a third insulating layer formed on the upper electrode;
a second contact plug electrically connected to the upper electrode through the third insulating layer; and
a metal wiring pattern formed on the third insulating layer and the second contact plug.

9. The resistive memory device of claim 8, wherein the third insulating layer has a second contact hole,
a second adhesive layer and a second diffusion barrier layer are formed on a bottom surface and an inner side surface of the second contact hole, and
the second contact plug is formed on the second diffusion barrier layer to fill the second contact hole.

10. A method of manufacturing a resistive memory device, the method comprising:
forming a lower electrode having a flat upper surface;
forming a resistance change layer on the lower electrode; and
forming an upper electrode on the resistance change layer,
wherein the upper surface of the lower electrode is wider than a lower surface of the lower electrode.

11. The method of claim 10, wherein the lower electrode has an inclined side surface so that a width of the lower electrode is increased upwardly.

12. The method of claim 10, further comprising:
forming a transistor on a substrate;
forming a first insulating layer on the substrate and the transistor;
forming a first contact plug electrically connected to the transistor through the first insulating layer;
forming a second insulating layer on the first insulating layer and the first contact plug; and
forming an opening exposing a portion of an upper surface of the first contact plug by partially removing the second insulating layer,
wherein the lower electrode is formed in the opening.

13. The method of claim 12, wherein the opening has an inclined inner side surface so that a width of the opening is increased upwardly.

14. The method of claim 12, wherein forming the opening comprises:
forming a photoresist pattern on the second insulating layer exposing a portion of the second insulating layer corresponding to the opening;
forming a recess in the second insulating layer by performing a first etching process using the photoresist pattern as an etching mask;
removing the photoresist pattern; and
forming the opening by performing a second etching process.

15. The method of claim 12, wherein forming the opening comprises:
forming a photoresist pattern having a first opening exposing a portion of the second insulating layer on the second insulating layer;
forming a second opening by performing a photoresist reflow process, the second opening having an inclined inner side surface so that a width of the second opening is increased upwardly; and
forming the opening by performing an etching process using the photoresist pattern as an etching mask.

16. The method of claim 12, wherein forming the lower electrode comprises:
forming a conductive layer on the second insulating layer and inner surfaces of the opening; and
removing a portion of the conductive layer to expose an upper surface of the second insulating layer to form the lower electrode in the opening.

17. The method of claim 12, further comprising:
forming a first contact hole exposing a portion of the transistor through the first insulating layer;
forming a first adhesive layer on a bottom surface and an inner side surface of the first contact hole; and
forming a first diffusion barrier layer on the first adhesive layer,
wherein the first contact plug is formed on the first diffusion barrier layer to fill the first contact hole.

18. The method of claim 17, wherein the resistance change layer is formed on the lower electrode and the second insulating layer and is electrically insulated from the first adhesive layer by the second insulating layer.

19. The method of claim 10, further comprising forming a conductive layer on the resistance change layer,
wherein the upper electrode is formed on the conductive layer.

20. The method of claim 10, further comprising:
forming a third insulating layer on the upper electrode;
forming a second contact plug electrically connected to the upper electrode through the third insulating layer; and
forming a metal wiring pattern on the third insulating layer and the second contact plug.
